(19) United States
(12) Patent Application Publication
(10) Pub. No.: US 2024/0379506 A1
(43) Pub. Date: Nov. 14, 2024

(54) ELECTRONIC DEVICE WITH IMPROVED LEADFRAME TRIMMING PROCESS

(71) Applicant: TEXAS INSTRUMENTS INCORPORATED, DALLAS, TX (US)

(72) Inventors: Lau Chun Lek, Kuala Lumpur (MY); Azman Alias, Kuala Lumpur (MY); Mohd Nizam Rohani, Kuala Lumpur (MY)

(21) Appl. No.: 18/314,585

(22) Filed: May 9, 2023

(51) Int. Cl. H01L 23/495; H01L 21/56; H01L 23/00; H01L 23/31

(52) U.S. Cl. CPC H01L 23/49513; H01L 21/561; H01L 23/3107; H01L 24/32; H01L 24/48; H01L 24/73; H01L 24/83; H01L 24/85; H01L 24/92; H01L 2224/32245; H01L 2224/48175; H01L 2224/73265; H01L 2224/83; H01L 2224/85; H01L 2224/92247

(57) ABSTRACT

A method of fabricating electronic devices includes providing an array of leadframes, the array of leadframes including leads, tie bars, and dam bars and attaching a die to each leadframe of the array of leadframes. Wire bonds are attached from an active side of the die to the leads on each leadframe of the array of leadframes. A mold compound is formed over the die, the wire bonds, and a portion of the leads on each leadframe of the array of leadframes. A multi-step trimming process is performed to the array of leadframes to remove the tie bars and the dam bars from each of the leadframes of the array of leadframes.

### TECHNICAL FIELD

The present disclosure relates to an electronic device and more specifically, to an integrated circuit package and method of making using a multi-step trimming process to remove tie bars and dam bars.

### BACKGROUND

Removal of dam bars and tie bars between leads of integrated circuit (IC) packages during a singulation process is an essential trimming process after encapsulation. Over time, premature wear of the cutting tool creates jagged cutting edges which leads to an uneven amount of mold flash remnant between the leads. This ultimately leads to IC package failure during downstream assembly processes. In addition, premature wear of the cutting tool leads to more frequent replacement of the cutting tool, which in turn leads to higher operating costs and loss of production.

### SUMMARY

In described examples, a method of fabricating electronic devices includes providing an array of leadframes, the array of leadframes including leads, tie bars, and dam bars and attaching a die to each leadframe of the array of leadframes. Wire bonds are attached from an active side of the die to the leads on each leadframe of the array of leadframes. A mold compound is formed over the die, the wire bonds, and a portion of the leads on each leadframe of the array of leadframes. A multi-step trimming process is performed to the array of leadframes to remove the tie bars and the dam bars from each of the leadframes of the array of leadframes.

In described examples, an electronic device includes an electronic device includes a leadframe having a die pad and leads and a die deposited on the die pad. Wire bonds are attached from an active side of the die to the leads. A mold compound encapsulates the die, the wire bonds, and a portion of the leads, wherein the electronic device is free from mold flash between a portion of the leads not encapsulated by the mold compound.

In still another described example, a method of singulating an array of electronic devices includes providing an array of leadframes, the array of leadframes including leads, tie bars, and dam bars and attaching a die to each leadframe of the array of leadframes. Wire bonds are attached from an active side of the die to the leads on each leadframe of the array of leadframes. A mold compound is formed over the die, the wire bonds, and a portion of the leads on each leadframe of the array of leadframes. A first trimming step removes the tie bars from the array of leadframes and a second trimming step removes the dam bars.

### BRIEF DESCRIPTION OF THE DRAWINGS

FIG. 1 illustrates a top view of an example partial array of example electronic devices.

FIGS. 2A and 2B illustrates top and cross-sectional views of an electronic device after undergoing a leadframe trimming process.

FIG. 3 is a block diagram flow-chart illustrating a fabrication process of electronic devices.

FIG. 4A illustrates a top view of an array of leadframes in the early stages of fabrication.

FIG. 4B illustrates a cross-sectional view of the fabrication of a single leadframe of FIG. 4A in the early stages of fabrication of an electronic device in FIGS. 2A and 2B.

FIG. 4C illustrates a cross-sectional view of the electronic device of FIG. 4B with a die attached to a die pad.

FIG. 4D illustrates a cross-sectional view of the electronic device of FIG. 4C with wire bonds attached to the dies and leadframe.

FIG. 4E is a cross-sectional view of the electronic device of FIG. 4D after the formation of a mold compound.

FIG. 4F illustrates a top view of the array of leadframes including the fabrication of the electronic device of FIG. 4E.

FIGS. 4G-4L illustrate a two-step trimming process to remove tie bars and dam bars from the array to singulate the electronic devices.

FIG. 4M illustrates a top view of the singulated electronic device of FIG. 4E.

FIG. 4N illustrates a cross-sectional view of the singulated electronic device of FIG. 4M after the formation of the leads.

### DETAILED DESCRIPTION

During fabrication of integrated circuit (IC) packages, removing dam bars and tie bars between leads of the IC packages during a singulation process is an essential trimming process after encapsulation. A cutting tool used in the singulation process is a flat edged punch that removes both the tie bars and the dam bars in a single cutting step. Over time, premature wear of the cutting tool creates jagged cutting edges on the IC packages which leads to an uneven amount of mold flash remnant between the leads. This ultimately leads to IC package failure during downstream assembly processes. In addition, premature wear of the cutting tool leads to improper or incomplete cutting of the dam bar. Thus, an uncut portion of the dam bar may remain between leads after the trimming process, which can cause slug pull back and intermittent shorting between leads. Still further, the premature wear of the cutting tool results in more frequent replacement of the cutting tool, which results in increased operating costs and loss of production.

Disclosed herein is an electronic device and method of fabricating the electronic device that overcomes the challenges described above. The method includes performing a multi-step trimming process to an array of leadframes to first remove the tie bars and second to remove the dam bars. A cutting tool is provided that includes an angular cutting tip and a punch portion. The angular cutting tip first removes the tie bars by shearing each tie bar at a point of contact with a mold compound of each IC package. The punch portion of the cutting tool removes the dam bars between the IC packages thereby singulating the IC packages. One advantage of the multi-step cutting process is that the angular tip of the cutting tool provides a clean cut at the point of contact between the tie bars and the mold compound of the IC package. In addition, with the tie bars already removed during the first cut, there is enough force to cleanly remove the dam bars during the second cut using the punch portion. Another advantage is that the multi-step cutting process reduces the wear on the cutting tool since the force required for each cut is reduced since the amount of material being removed with each cut is reduced.

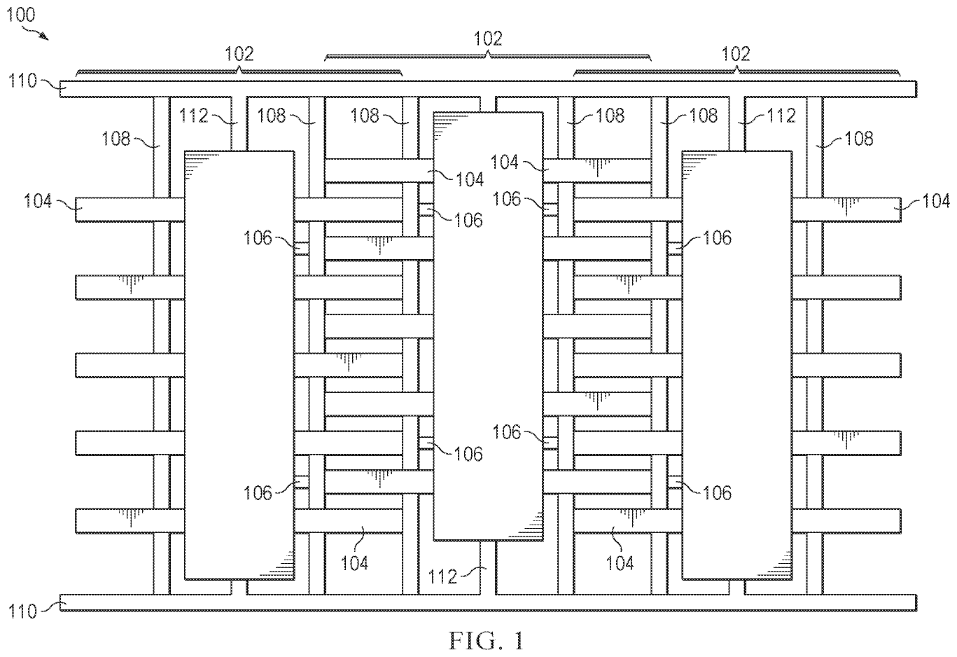

FIG. 1 is a top view of an example partial array 100 of example electronic devices 102 having outer (external) leads 104. The example partial array 100 illustrated in FIG. 1 includes three electronic devices 102 connected together. It is understood, however, that a full array will include an appropriate number of electronic devices designed to occupy the array. Thus, the example illustrated in FIG. 1 is for simplicity and illustrative purposes only, and is not intended to limit the scope of the invention. The electronic devices 102 may be comprised of an integrated circuit (IC) package that includes outer leads including, but not limited to, a single in-line package (SIP) or a dual in-line package (DIP).

The partial array 100 includes tie bars 106 that connect some, but not all, adjacent outer leads 104 of the electronic devices 102 together. The partial array 100 further includes dam bars 108 that connect the outer leads 104 on adjacent electronic devices 102 together. A support frame comprised of side rails 110 and support bars 112 provide support for the array. Specifically, as will be explained in further detail below, the dam bars 108 are connected to the side rails 110 of the support frame and the support bars 112 provide a connection between a die pad (described below) and the side rails 110.

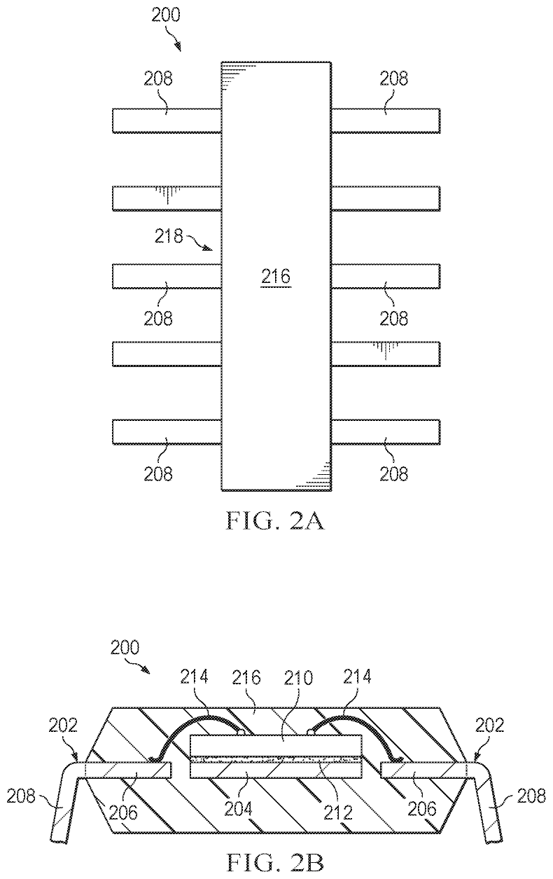

FIG. 2A is top view and FIG. 2B is an enlarged cross-sectional view of FIG. 2A of an electronic device 200 after it has been singulated from an array of electronic devices, such as the partial array 100 illustrated in FIG. 1, using the method described below. The electronic device 200 includes a leadframe 202 having a die pad 204, inner (internal) leads 206, and outer (external) leads 208 that are connected to the inner leads 206. A die 210 is attached to the die pad 204 via a die attach material 212 (e.g., solder, epoxy, etc.). Wire bonds 214 are connected from the die 210 to the inner leads 206. A mold compound 216 encapsulates the die pad 204, the inner leads 206, the die 210, and the wire bonds 214. The mold compound 216, however, does not encapsulate the outer leads 208.

As illustrated in FIG. 2A, after the electronic devices are singulated using the method described below, the mold flash 218 between the outer leads 208 is even. In other words, there is no uneven mold flash 218 between the outer leads 208, which is not encapsulated by the mold compound 216 due to the configuration of a trimming device and the nature of the trimming process to remove the tie bars 106 and the dam bars 108. In addition, the improved trimming process eliminates the presence of slugs (remnants of tie bars 106 and/or dam bars 108 that are not completely removed during the trimming process), which damage the mold compound 216 (slug pull back) and cause intermittent shorting between the inner leads 206 and/or the outer leads 208.

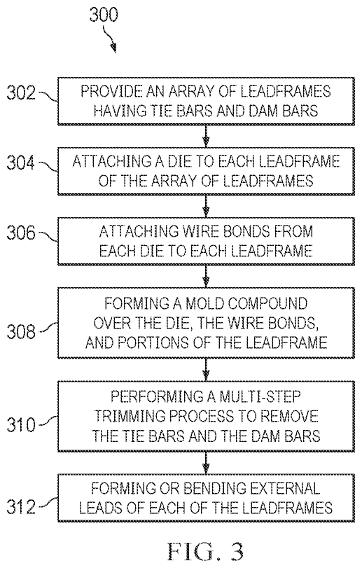

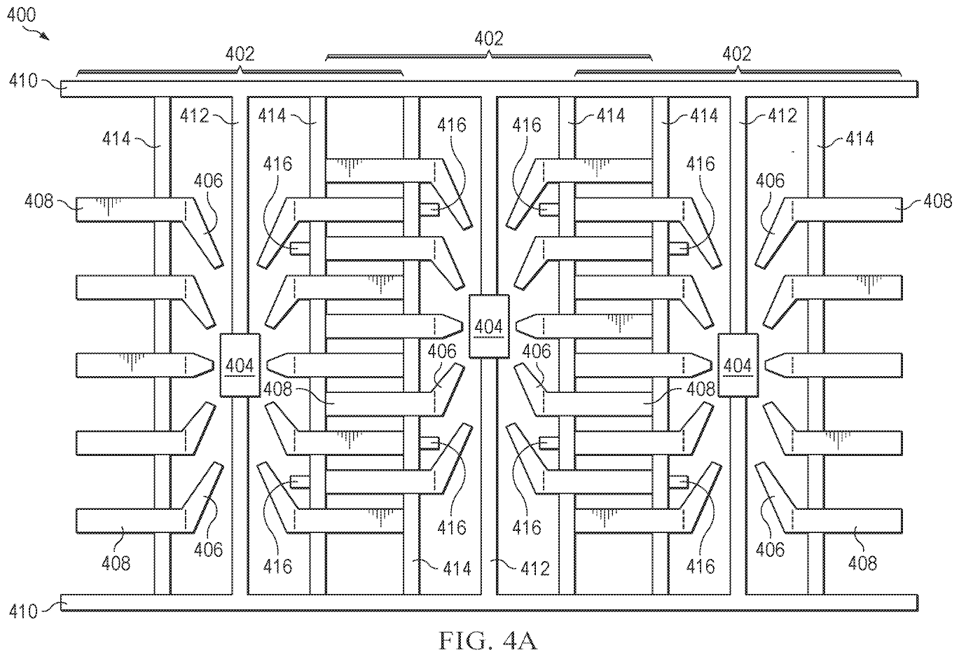

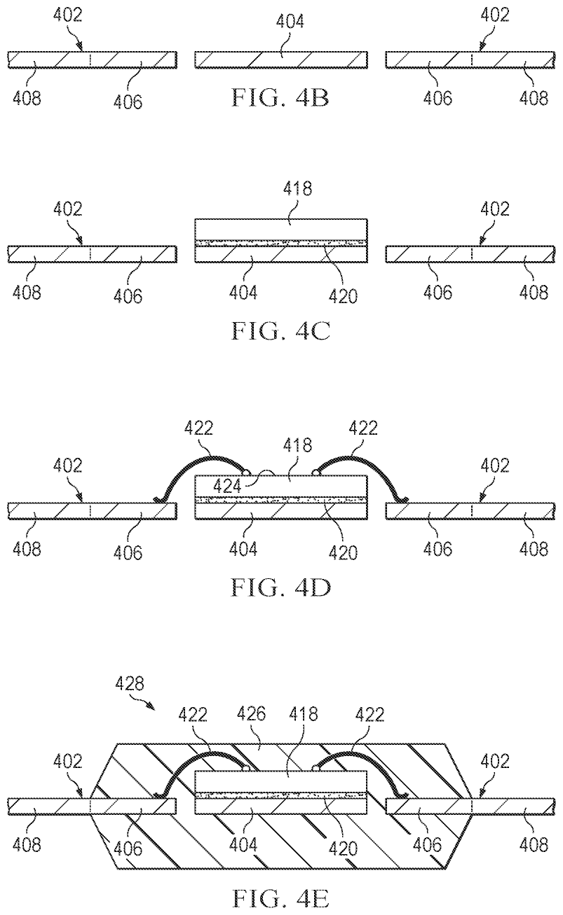

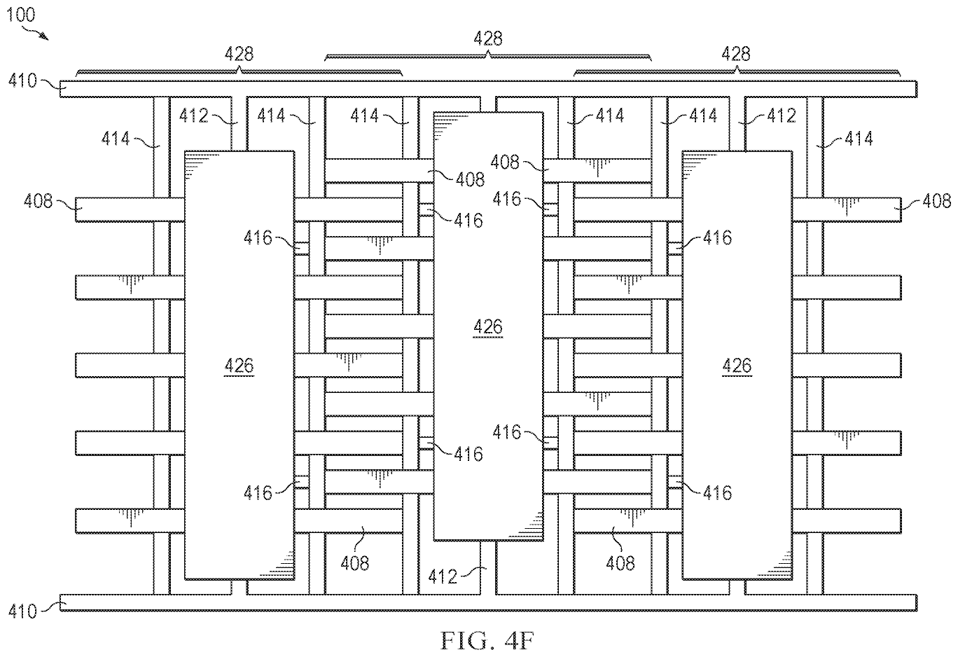

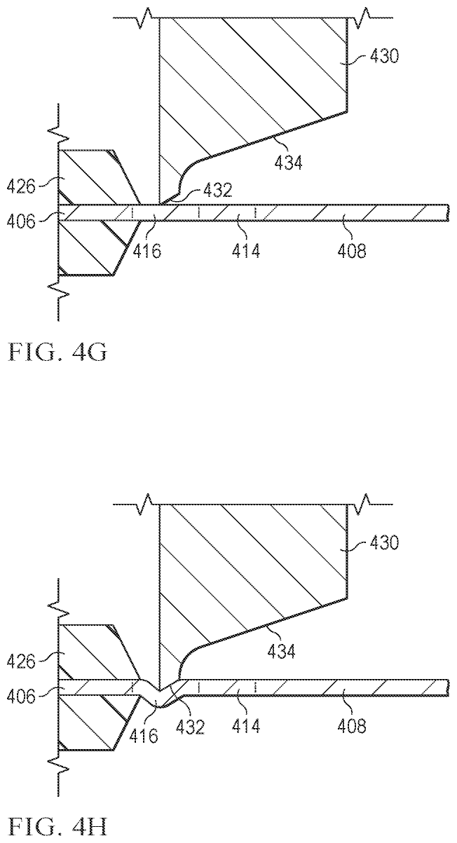

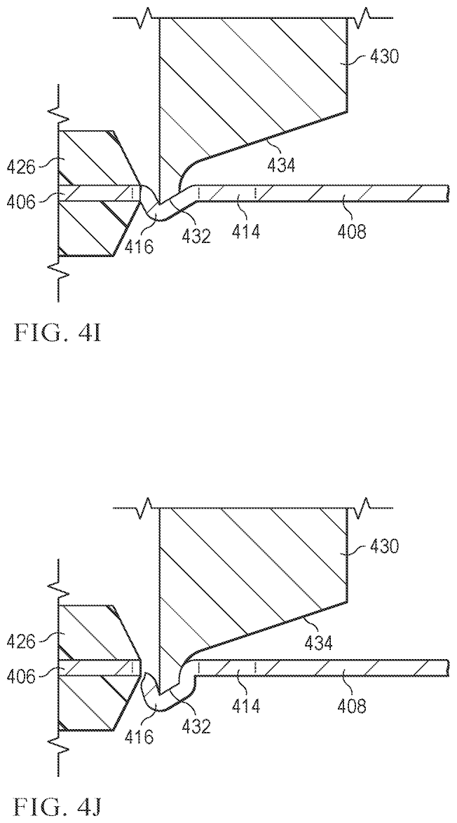

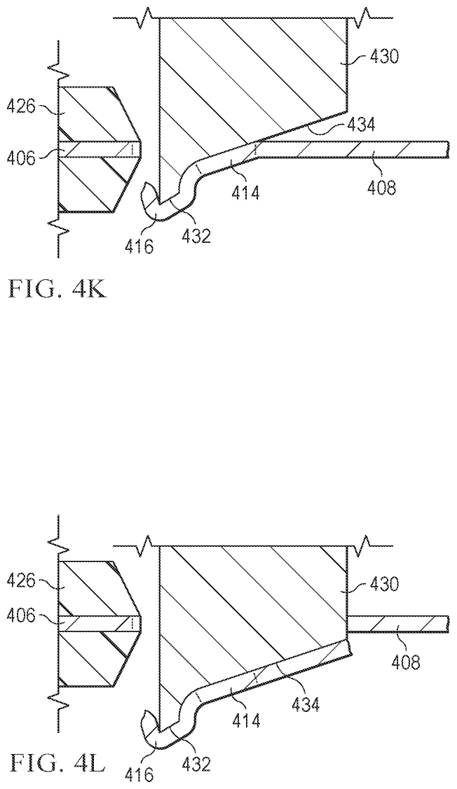

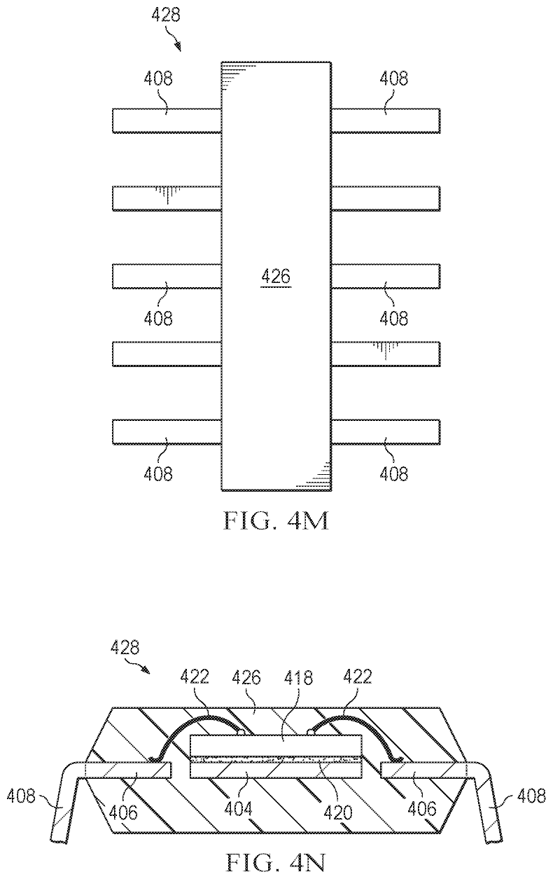

FIG. 3 is a block diagram flow chart explaining a fabrication process 300 and FIGS. 4A-4N illustrate the fabrication process associated with the formation of the electronic device 200 illustrated in FIGS. 2A and 2B. Though depicted sequentially as a matter of convenience, at least some of the actions shown can be performed in a different order and/or performed in parallel. Alternatively, some implementations may perform only some of the actions shown. Still further, although the example illustrated in FIGS. 3 and 4A-4N is an example method illustrating the example configuration of FIGS. 2A and 2B, other methods and configurations are possible.

Referring to FIGS. 3 and 4A, the fabrication process begins with an array 400 of leadframes 402, as illustrated in the top view illustration in FIG. 4A. Each leadframe 402 includes a die pad 404, and leads comprised of inner (internal) leads 406 and outer (external) leads 408 where the inner and outer leads 406, 408 are connected. The array 400 of leadframes 402 are connected to each other with a support frame that includes side rails 410 and support bars 412. Dam bars 414 are connected to opposite side rails 410 and are interconnected to the leads to support the leads during the fabrication process. The support bars 412 are connected to each respective side rail 410 at one end and the die pad 404 at an opposite end. Thus, the support bars 412 provide support for the die pad 404 during the fabrication process. Tic bars 416 are provided and connect some, but not all, adjacent outer leads 408 of the leadframes 402 together for additional support.

FIGS. 4B-4E are cross-sectional views illustrating the fabrication process for each electronic device in the array 400. For simplicity, only a single electronic device is illustrated in FIGS. 4B-4E. It is understood, however, that the process illustrated in FIGS. 4B-4E applies to the array 400 of electronic devices. Thus, after fabrication of the array of electronic devices the array is singulated to separate each electronic device from the array 400. The process starts at 302 with the leadframe 402 as illustrated in FIG. 4B. At 304, a die 418 is attached to the die pad 404 via a die attach material 420 resulting in the configuration in FIG. 4C. At 306, wire bonds 422 are attached from an active side 424 of the die 418 to the inner leads 406 resulting in the configuration in FIG. 4D. At 308, a mold compound 426 is added such that the mold compound 426 encapsulates the die pad 404, the inner leads 406, the die 418, and the wire bonds 422 resulting in an electronic device 428 in FIG. 4E. The mold compound 426, however, does not encapsulate the outer leads 408. At this stage of fabrication, the electronic device 428 is still attached to the array 400 as illustrated in the top view illustration in FIG. 4F, which illustrates three electronic devices 428 attached to the array 400.

At 310, FIGS. 4G-4L illustrate a two-step trimming process to remove, via a trimming or cutting process, both the tie bars 416 and the dam bars 414 from the electronic devices 428 to thereby singulate the electronic devices 428 from the array 400 and each other. Referring to FIG. 4G, the trimming process begins with a cutting device 430. The cutting device 430 includes an angular cutting tip 432 and a punch 434. In FIG. 4H, the cutting device 430 descends on the tie bar 416 and engages the tie bar 416 to begin a first cutting step in the two-step trimming process. In FIG. 4I, the cutting device 430 continues its descent on to the tic bar 416. In FIG. 4J, the tie bar 416 is completely removed from the leadframe 402 thereby leaving a clean cut without any remaining mold flash. In FIG. 4K, the punch 434 of the cutting device 430 engages the dam bar 414 thereby initializing the second cutting step in the two-step trimming process. In FIG. 4L, the punch 434 cuts away the dam bar 414 thereby completing the two-step trimming process and thus, singulating the electronic devices 428 from the array 400 and each other resulting in the electronic device 428 illustrated in FIG. 4M. Finally, at 312, the outer leads 408 are formed (bent) in a direction away from the active side 424 of the die 418 resulting in the electronic device 428 in FIG. 4N.

As mentioned above, the two-step cutting process coupled with the cutting device creates clean cuts to remove the tie bars and the dam bars thereby minimizing mold flash and slug remnants. In addition, the two-step cutting process reduces premature wearing of the cutting device since the force required for each cut is reduced since the amount of material being removed with each cut is reduced.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method of fabricating electronic devices comprising:
providing an array of leadframes, the array of leadframes including leads, tie bars, and dam bars;
attaching a die to each leadframe of the array of leadframes;
attaching wire bonds from an active side of the die to the leads on each leadframe of the array of leadframes;
forming a mold compound over the die, the wire bonds, and a portion of the leads on each leadframe of the array of leadframes;
performing a multi-step trimming process to the array of leadframes to remove the tie bars and the dam bars from each of the leadframes of the array of leadframes.

2. The method of claim 1, wherein performing a multi-step trimming process to the array of leadframes to remove the tie bars and the dam bars from each of the leadframes of the array of leadframes includes providing a cutting device having an angular cutting tip and a punch, performing a first trimming step with the angular cutting tip to remove the tie bars from the array of leadframes, and performing a second trimming step with the punch to remove the dam bars.

3. The method of claim 2, wherein performing a first trimming step with the angular cutting tip to remove the tie bars from the array of leadframes, and performing a second trimming step with the punch to remove the dam bars leaves the electronic devices and specifically, the mold compound free from mold flash.

4. The method of claim 1 further comprising forming the leads to bend in a direction toward or away from the active side of the die.

5. The method of claim 1, wherein the leads include inner leads and outer leads, wherein attaching wire bonds from an active side of the die to the leads on each leadframe of the array of leadframes includes attaching the wire bonds from the active side of the die to the inner leads.

6. The method of claim 5, wherein the mold compound is formed over the inner leads.

7. The method of claim 1, wherein attaching a die to each leadframe of the array of leadframes includes depositing a die attach material onto a die pad of each leadframe in the array of leadframes and depositing the die onto the die attach material.

8. An electronic device comprising:
a leadframe having a die pad and leads;
a die deposited on the die pad;
wire bonds attached from an active side of the die to the leads; and
a mold compound encapsulating the die, the wire bonds, and a portion of the leads,
wherein the electronic device is free from mold flash between a portion of the leads not encapsulated by the mold compound.

9. The electronic device of claim 8, wherein the leads are comprised of inner leads and outer leads.

10. The electronic device of claim 9, wherein the wire bonds are attached from the active side of the die to the inner leads.

11. The electronic device of claim 8, wherein the mold compound encapsulates the inner leads.

12. The electronic device of claim 8, wherein the die is attached to the die pad via a die attach material.

13. A method of singulating an array of electronic devices comprising:
providing an array of leadframes, the array of leadframes including leads, tie bars, and dam bars;
attaching a die to each leadframe of the array of leadframes;
attaching wire bonds from an active side of the die to the leads on each leadframe of the array of leadframes;
forming a mold compound over the die, the wire bonds, and a portion of the leads on each leadframe of the array of leadframes;
performing a first trimming step to remove the tie bars from the array of leadframes; and
performing a second trimming step to remove the dam bars.

14. The method of claim 13, wherein performing a first trimming step to remove the tie bars from the array of leadframes includes providing a cutting device having an angular cutting tip and a punch and removing the tie bars with the angular cutting tip.

15. The method of claim 14, wherein performing a second trimming step to remove the dam bars includes removing the dam bars with the punch.

16. The method of claim 15, wherein removing the tie bars with the angular cutting tip and removing the dam bars with the punch leaves the electronic device and specifically, the mold compound free from mold flash.

17. The method of claim 13 further comprising forming the leads to bend in a direction toward or away from the active side of the die.

18. The method of claim 13, wherein the leads include inner leads and outer leads, wherein attaching wire bonds from the active side of the die to the leads on each leadframe of the array of leadframes includes attaching the wire bonds from the active side of the die to the inner leads.

19. The method of claim 18, wherein the mold compound is formed over the inner leads.

20. The method of claim 13, wherein attaching a die to each leadframe of the array of leadframes includes depositing a die attach material onto a die pad of each leadframe in the array of leadframes and depositing the die onto the die attach material.
